(19) United States
(12) Patent Application Publication
(10) Pub. No.: US 2022/0367776 A1
(43) Pub. Date: Nov. 17, 2022

(54) Display Panel, Display Backplane and Manufacturing Method of Display Backplane

(71) Applicant: CHONGQING KONKA PHOTOELECTRIC TECHNOLOGY RESEARCH INSTITUTE CO., LTD., Chongqing (CN)

(72) Inventors: LI-WEI KUNG, Chongqing (CN); Fei PAN, Chongqing (CN)

(21) Appl. No.: 17/859,024

(22) Filed: Jul. 7, 2022

Related U.S. Application Data
(63) Continuation of application No. PCT/CN2021/093849, filed on May 14, 2021.

(51) Int. Cl. H01L 33/62; H01L 25/075; H01L 33/54; H01L 23/50

(52) U.S. Cl. CPC H01L 33/62; H01L 25/0753; H01L 33/54; H01L 23/50; H01L 2933/0066; H01L 2933/005

(57) ABSTRACT

The application relates to a display panel, a display backplane and a manufacturing method of the display backplane. A metal circuit connection area on a top surface of a substrate baseplate configured for electrical connection to the outside serves as a second conductor layer to be transferred to a bottom surface for arrangement, and a driving circuit on the top surface of the substrate is electrically connected to the second conductor layer on the bottom surface through a binding layer on a side surface of the substrate baseplate.

### TECHNICAL FIELD

The application relates to the field of display, in particular to a display panel, a display backplane and a manufacturing method of the display backplane.

### BACKGROUND

Micro LED is sought after by various manufacturers due to high brightness, wide color gamut coverage and high contrast ratio thereof, which is called a next generation display device with the popularity continuously rising in recent years. However, there are still many problems to be overcome in an actual production process. For example, Micro LED is limited by the huge transfer yield and efficiency, and a main application scenario is on a small-size display panel. For a large-size display with a size of more than 100 inches, such as 4K/8K, it is usually necessary to splice a plurality of display panels to form a large-size display. The larger the size is, the more display panels need to be spliced. On a display backplane of a single display panel, both the Micro LED and a driving circuit are arranged on a top surface of the display backplane, and a metal circuit connection area for electrically connecting the driving circuit to the outside needs to be reserved at the edge of the top surface, resulting in a wide side frame of the single display panel. However, after a plurality of display panels are spliced, a gap where the display panels are spliced is at least twice the width of the side frame of a single display panel, which will affect the visual effect and viewing experience to a large extent.

Therefore, how to reduce the side frame width of the display panel is an urgent problem to be solved.

### Technical Problem

In view of the above shortcomings of a conventional art, the application aims to provide a display panel, a display backplane and a manufacturing method of the display backplane, aiming at solving the problem of how to reduce the side frame width of the display panel.

### SUMMARY

A display backplane includes:

a substrate baseplate, the substrate baseplate being provided with a top surface and a bottom surface which are opposite to each other, the top surface being provided with a driving circuit for driving a micro light-emitting chip, the driving circuit including a chip bonding area circuit and at least two mutually insulated first conductor layers connected to the chip bonding area circuit, one end of each first conductor layer extending to a side surface of the substrate baseplate and being flush with the side surface, and the bottom surface being provided with at least two mutually insulated second conductor layers corresponding to the at least two first conductor layers;

an encapsulation layer arranged on the top surface; and

at least two binding layers attached to the side surface and electrically connecting the corresponding first conductor layer and second conductor layer respectively;

wherein the at least two binding layers are mutually insulated. The end, extending to the side surface, of the first conductor layer is attached to an inner surface of the binding layer, and an upper end of the binding layer is higher than the top surface and combined with the encapsulation layer arranged on the top surface. The inner surface of the binding layer is the surface, close to the substrate baseplate, of the binding layer, and the upper end of the binding layer is the end, close to the top surface, of the binding layer.

In the display backplane, a driving circuit for driving a micro light-emitting chip is arranged on the top surface of the substrate baseplate, and one end of a first conductor layer of the driving circuit extends to the side surface of the substrate baseplate and is flush with the side surface. The bottom surface opposite to the top surface is provided with a second conductor layer corresponding to the first conductor layer, then a binding layer for electrically connecting the corresponding first conductor layer and second conductor layer is formed on the side surface so as to implement electrical connection between the driving circuit on the top surface and the second conductor layer on the bottom surface, and electrical connection to the outside may be implemented through the second conductor layer. Therefore, the metal circuit connection area does not need to be reserved on the top surface of the substrate baseplate any more, and the side frame width of the display backplane may be reduced. In addition, an upper end of the binding layer arranged on the side surface of the substrate baseplate is higher than the top surface of the substrate baseplate, and is combined with the encapsulation layer formed on the top surface, so that the combination between the binding layer and the above side surface may be improved, the situation that the binding layer falls off or is loosened from the side surface to cause poor conductivity may be avoided, and the yield and reliability of the display backplane are improved.

Based on the same inventive concept, the application also provides a manufacturing method of the display backplane, which includes the following operations.

A driving circuit is manufactured on a top surface of a substrate baseplate, the driving circuit including a chip bonding area circuit and at least two mutually insulated first conductor layers connected to the chip bonding area circuit, one end of each first conductor layer extending to a side surface of the substrate baseplate and being flush with the side surface of the substrate baseplate, a bottom surface of the substrate baseplate being provided with at least two mutually insulated second conductor layers corresponding to the at least two first conductor layers, and the top surface and the bottom surface being two opposite surfaces of the substrate baseplate.

An encapsulation layer is formed on the top surface, and a side surface of the encapsulation layer is flush with the side surface of the substrate baseplate.

At least two binding layers, which electrically connect the corresponding first conductor layer and second conductor layer are formed on the side surfaces of the substrate baseplate and the side surfaces of the encapsulation layer, the at least two binding layers formed being mutually insulated, the end, extending to the side surface, of the first conductor layer being attached to an inner surface of the binding layer, an upper end of the binding layer being higher than the top surface and combined with the encapsulation layer, the inner surface of the binding layer being the surface, close to the substrate baseplate, of the binding layer, and the upper end of the binding layer being the end, close to the top surface, of the binding layer.

The display backplane manufactured by the manufacturing method of the display backplane has a narrow side frame, and the manufactured binding layer is not only attached to the side surface of the substrate baseplate, but the upper end thereof is also higher than the top surface of the substrate baseplate, so that combination with the encapsulation layer may be achieved, the attachment firmness of the binding layer may be improved, the situation that the binding layer falls off or loosens from the side surface to cause poor conductivity is avoided, the manufacturing yield of the display backplane is improved, and the cost is reduced.

Based on the same inventive concept, the application also provides a display panel, which includes the display backplane as described above.

For the display panel, as the above display backplane has a narrow side frame, the display panel also has a narrow side frame, and the visual effect and viewing experience may be improved. Moreover, the binding layer is not only attached to the side surface of the substrate baseplate, but the upper end thereof is also higher than the top surface of the substrate baseplate, so that the attachment firmness of the binding layer may be guaranteed by combination with the encapsulation layer, the situation that the binding layer falls off or loosens from the side surface to cause poor conductivity is avoided, and the yield and reliability of the display panel are improved.

### Beneficial Effect

According to the display panel, the display backplane and the manufacturing method of the display backplane provided by the application, the driving circuit for driving the micro light-emitting chip is arranged on the top surface of the substrate baseplate, and one end of the first conductor layer of the driving circuit extends to the side surface of the substrate baseplate and is flush with the side surface. The bottom surface opposite to the top surface is provided with the second conductor layer corresponding to the first conductor layer, then the binding layer for electrically connecting the corresponding first conductor layer and second conductor layer is formed on the side surface so as to implement electrical connection between the driving circuit on the top surface and the second conductor layer on the bottom surface. Therefore, the metal circuit connection area does not need to be reserved on the top surface of the substrate baseplate any more, and the side frame width of the display backplane may be reduced. In addition, the upper end of the binding layer arranged on the side surface of the substrate baseplate is higher than the top surface of the substrate baseplate, and is combined with the encapsulation layer formed on the top surface, so that the combination strength between the binding layer and the above side surface may be improved.

### BRIEF DESCRIPTION OF THE DRAWINGS

FIG. 1-A is a three-dimensional schematic diagram I of a substrate baseplate according to an embodiment of the application.

FIG. 1-B is a sectional view of a substrate baseplate according to an embodiment of the application.

FIG. 2-A is a sectional view I of a display backplane according to an embodiment of the application.

FIG. 2-B is a sectional view II of a display backplane according to an embodiment of the application.

FIG. 2-C is a sectional view III of a display backplane according to an embodiment of the application.

FIG. 2-D is a sectional view IV of a display backplane according to an embodiment of the application.

FIG. 2-E is a sectional view V of a display backplane according to an embodiment of the application.

FIG. 3-A is a sectional view VI of a display backplane according to an embodiment of the application.

FIG. 3-B is a sectional view VII of a display backplane according to an embodiment of the application.

FIG. 3-C is a sectional view VIII of a display backplane according to an embodiment of the application.

FIG. 4 is a three-dimensional schematic diagram II of a substrate baseplate according to an embodiment of the application.

FIG. 5-A is a sectional view IX of a display backplane according to an embodiment of the application.

FIG. 5-B is a sectional view X of a display backplane according to an embodiment of the application.

FIG. 5-C is a sectional view XI of a display backplane according to an embodiment of the application.

FIG. 6-A is a sectional view XII of a display backplane according to an embodiment of the application.

FIG. 6-B is a sectional view XIII of a display backplane according to an embodiment of the application.

FIG. 7 is a sectional view XIV of a display backplane according to an embodiment of the application.

FIG. 8-A is a flowchart of a manufacturing method of a display backplane according to another embodiment of the application.

FIG. 8-B is a top view I of a display backplane according to another embodiment of the application.

FIG. 8-C is a top view II of a display backplane according to another embodiment of the application.

FIG. 8-D is a top view III of a display backplane according to another embodiment of the application.

FIG. 8-E is a flowchart of manufacturing a binding layer according to another embodiment of the application.

FIG. 8-F is a structural schematic diagram of a strippable glue layer according to another embodiment of the application.

FIG. 8-G is a structural schematic diagram after removal of a strippable glue layer according to another embodiment of the application.

FIG. 8-H is a structural schematic diagram of a protective layer formed on a display backplane according to another embodiment of the application.

FIG. 8-I is a structural schematic diagram of another strippable glue layer according to another embodiment of the application.

FIG. 8-J is a structural schematic diagram after removal of another strippable glue layer according to another embodiment of the application.

FIG. 8-K is a structural schematic diagram of a binding layer formed on another display backplane according to another embodiment of the application.

FIG. 9-A is a flowchart of a manufacturing method of a display backplane according to another embodiment of the application.

FIG. 9-B is a structural schematic diagram after bonding of the micro light-emitting chip is completed on the top surface of the substrate baseplate according to another embodiment of the application.

FIG. 10-A is a flowchart of a manufacturing method of a display backplane according to yet another embodiment of the application.

FIG. 10-B is a top view I of a display backplane according to yet another embodiment of the application.

FIG. 10-C is a top view II of a display backplane according to yet another embodiment of the application.

FIG. 10-D is a top view III of a display backplane according to yet another embodiment of the application.

FIG. 10-E is a top view IV of a display backplane according to yet another embodiment of the application.

FIG. 10-F is a cutting schematic diagram of a display backplane according to yet another embodiment of the application.

FIG. 10-G is a sectional view of a first conductor layer formed on a display backplane according to yet another embodiment of the application.

FIG. 10-H is a three-dimensional diagram of a first conductor layer formed on a display backplane according to yet another embodiment of the application.

FIG. 10-I is a three-dimensional diagram I of a protective layer formed on a display backplane according to yet another embodiment of the application.

FIG. 10-J is a three-dimensional diagram II of a protective layer formed on a display backplane according to yet another embodiment of the application.

### REFERENCE SIGNS IN THE DRAWINGS

1—substrate baseplate, 10—bonding area, 11—first conductor layer, 12—second conductor layer, 13—binding layer, 131—upper end of binding layer, 132—lower end of binding layer, 100—chamfered area, 101—rounded area, 14—protective layer, 2—micro light-emitting chip, 30—photoresist layer, 31—second black glue layer, 32—translucent glue layer, 33—gray glue layer, and 40—strippable glue layer.

### DETAILED DESCRIPTION OF THE EMBODIMENTS

In order to facilitate the understanding of the application, the application will be described more comprehensively below with reference to the relevant drawings. Preferred implementation modes of the application are given in the attached drawings. However, the application may be implemented in many different forms and is not limited to the implementation modes described herein. On the contrary, these implementation modes are provided for the purpose of making the disclosure of the application more thorough and comprehensive.

Unless otherwise defined, all technological and scientific terms used in the present application have meanings the same as those usually understood by those skilled in the art of the application. Terms used in the description of the present application are only adopted to describe the purpose of the specific implementation modes and not intended to limit the application.

In a related art, on a display panel, both an LED chip and a driving circuit are arranged on a top surface of a display backplane, and a metal circuit connection area for electrically connecting the driving circuit to the outside is reserved at the edge of the top surface, resulting in a wide side frame of the display panel. However, when a plurality of display panels are spliced to form a large-size display screen, a gap where the display panels are spliced is at least twice the width of the side frame of a single display panel, which will affect the visual effect and viewing experience to a large extent.

Based thereon, the application expects to provide a solution to the above-mentioned technical problems, the details of which will be explained in the following embodiments.

The embodiments provide a display backplane. A second conductor layer for external connection is arranged on a bottom surface of a substrate baseplate, and a binding layer with conductivity is arranged on a side surface of the substrate baseplate, so that a driving circuit on a top surface of the substrate baseplate is electrically connected with the second conductor layer on the bottom surface. Then the driving circuit is electrically connected to the outside through the second conductor layer, so that a metal circuit connection area electrically connected to the outside does not need to be reserved on the top surface of the substrate baseplate, and the side frame width of the substrate baseplate can be reduced. The upper end of the binding layer arranged on the side surface of the substrate baseplate is also combined with an encapsulation layer formed on the top surface of the substrate baseplate, so that the attachment firmness of the binding layer may be improved, and the situation that the binding layer falls off or loosens from the side surface to cause poor conductivity may be avoided.

For the convenience of understanding, the display backplane is illustrated in the following embodiment with reference to the drawings.

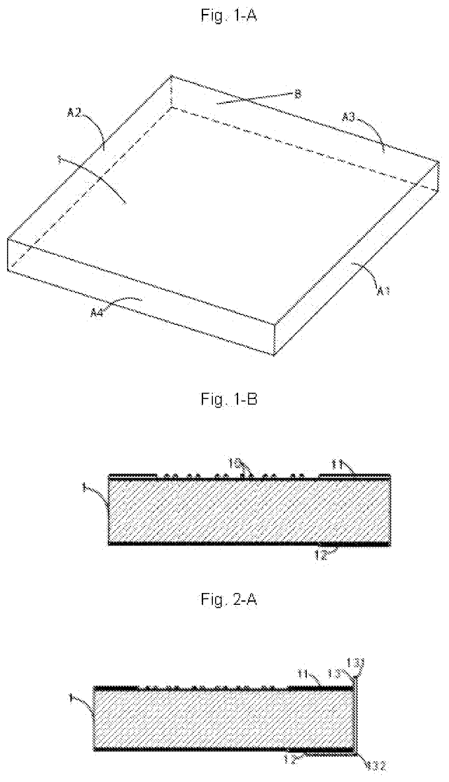

The display backplane provided by the embodiment includes a substrate baseplate 1 shown in FIGS. 1-A and 1-B, and the substrate baseplate 1 has a top surface (indicated by a marker B in the figure, which may also be called a front surface) and a bottom surface (which may also be called a back surface) opposite to the top surface. It is to be understood that the shape of the substrate baseplate 1 in the embodiment may be flexibly set according to requirements, such as but not limited to a regular shape such as a rectangle, a sector, a circle, a rhombus and a regular hexagon, and may also be set into an irregular shape according to requirements, which will not be described in detail here. In addition, the material of the substrate baseplate 1 in the embodiment may also be set according to application requirements, such as but not limited to a glass substrate, a Printed Circuit Board (PCB) substrate and a silicon substrate.

In the embodiment, the top surface of the base substrate 1 is provided with a driving circuit for driving a micro light-emitting chip, and the micro light-emitting chip in the embodiment refers to an um-class light-emitting chip, such as but not limited to at least one of a Mini LED chip and a Micro LED chip. Of course, the micro light-emitting chip may also be replaced with a chip of another size according to the requirements, which will not be described in detail here.

The driving circuit in the embodiment includes a chip bonding area circuit and at least two mutually insulated first conductor layers electrically connected to the chip bonding area circuit, and one end of the first conductor layer extends to the side surface of the substrate baseplate 1 and is flush with the side surface. In an example of the embodiment, as shown in FIG. 1-B, the chip bonding area circuit may include, but is not limited to, bonding areas 10 corresponding to positive and negative leads of each micro light-emitting chip. The bonding area specifically includes corresponding positive and negative bonding areas. The first conductor layer 11 may include, but is not limited to, at least two mutually insulated conductor layers electrically connected to the positive and negative bonding areas correspondingly. Of course, it is to be understood that the driving circuit may also be provided with a bonding area electrically connected to another device correspondingly and a corresponding first conductor layer according to requirements. It is to be understood that, in the embodiment, the end, extending to the side surface of the substrate baseplate 1, of the first conductor layer 11 may be the end, away from the driving circuit, of the first conductor layer. And the end is flush with the side surface of the substrate baseplate 1, that is, the end face of the end is located on the same plane as the side surface of the substrate baseplate 1.

It is to be understood that each first conductor layer 11 in the embodiment may extend to the same side surface of the substrate baseplate 1 and may also extend to a different side surface of the substrate baseplate 1. For the convenience of understanding, description is made below with the substrate baseplate 1 shown in FIG. 1-A as an example. The substrate baseplate 1 includes four side surfaces A1 to A4, and the first conductor layers 11 thereon may all extend to one of the side surfaces, for example, all extending to A1. The first conductor layers 11 thereon may also extend to two side surfaces which are opposite to each other, for example, extending to A1 and A2, or A3 and A4, respectively. Or the first conductor layers 11 thereon may extend to two side surfaces which are adjacent to each other, for example, extending to A1 and A3, or A2 and M, respectively. Of course, the first conductor layers 11 thereon may also extend to three side surfaces or four side surfaces according to requirements, which will not be described in detail here.

In the embodiment, the bottom surface of the substrate baseplate 1 is provided with at least two mutually insulated second conductor layers corresponding to the first conductor layers. It is to be understood that the correspondence between the first conductor layer and the second conductor layer in the embodiment may be flexibly set. For example, same may be set to one-to-one correspondence, and may also be set to one-to-multi or multi-to-one, etc. according to requirements, which will not be described in detail here.

In the embodiment, the second conductor layer may not extend to the side surface of the substrate baseplate 1, and may also extend to the side surface of the substrate baseplate 1. At the moment, the second conductor layer may specifically extend to the side surface where the corresponding first conductor layer is located, may be flush with the side surface, for example, as shown in the second conductor layer 12 in FIG. 1-B, and of course may not be flush as well. The second conductor layer may be used as a conductor layer for external connection, so that after the first conductor layer is electrically connected, the driving circuit is electrically connected to the outside. Therefore, it is no longer necessary to reserve a metal circuit connection area on the top surface of the substrate baseplate 1, which may reduce the side frame width of the display backplane, and even achieve the effect of no side frame in visual effect. When the display backplanes are spliced to form a large display screen, the width of a splicing gap between adjacent display backplanes after being spliced may be basically consistent with the distance between adjacent light-emitting chips in a display area of each display backplane, and seamless effect may basically achieved in visual effect.

In the embodiment, the display backplane further includes at least two binding layers attached to the side surface of the substrate baseplate 1 and electrically connecting the corresponding first conductor layer and second conductor layer. Herein, the at least two binding layers are insulated from each other. The end, extending to the side surface, of the first conductor layer is attached to an inner surface of the binding layer, and an upper end of the binding layer is higher than the top surface and combined with an encapsulation layer (not shown in the figure) arranged on the top surface. In the embodiment, the inner surface of the binding layer is the surface, close to the substrate baseplate, of the binding layer, that is, the surface attached to the substrate baseplate, and the upper end of the binding layer is the end, close to the top surface, of the binding layer.

It is to be understood that in some application examples of the embodiment, when electrodes of some two binding layers have the same polarity, both may also not be insulated from each other. Similarly, the first conductor layer and the second conductor layer may be similarly arranged, and these equivalent and alternative arrangements will not be described in detail here.

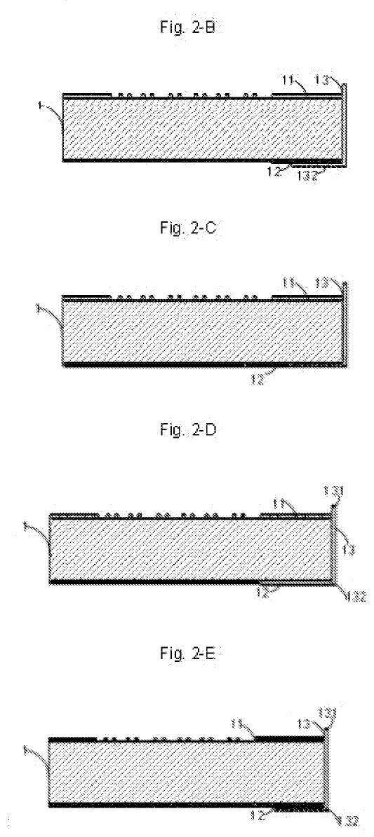

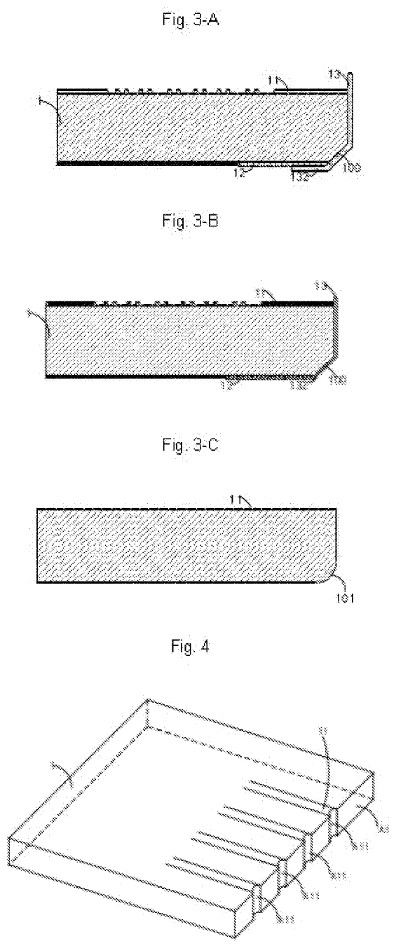

For the convenience of understanding, easy-to-understand description is made below to the structure, electrically connecting the corresponding first conductor layer and second conductor layer, of the binding layer with reference to examples shown in FIGS. 2-A to 2-D.

As shown in FIGS. 2-A to 2-D, the end, extending to the side surface of the substrate baseplate 1, of the first conductor layer 11 is flush with the side surface, and the binding layer 13 attached to the side surface of the substrate baseplate 1 electrically connects the first conductor layer 11 to the second conductor layer 12 corresponding thereto. Herein, the end, extending to the side surface, of the first conductor layer 11 is attached to the inner surface of the binding layer 13 (that is, the surface where the binding layer 13 is attached to the side surface of the substrate baseplate 1 in the figure). The upper end 131 of the binding layer 13 is higher than the top surface of the substrate baseplate 1 and combined with the encapsulation layer (not shown in the figure) arranged on the top surface. In the embodiment, the binding layer 13 does not extend to the top surface of the substrate baseplate 1, so the area of the top surface of the substrate baseplate 1 is not occupied as well, and the side frame width of the manufactured display backplane may be further reduced. However, in order to ensure the attachment firmness of the binding layer 13, the upper end 131 of the binding layer 13 is set higher than the top surface of the substrate baseplate 1, and is combined with the encapsulation layer on the top surface. Moreover, it is to be understood that the combination mode between the upper end 131 and the encapsulation layer may be flexibly set, which will be illustrated subsequently.

In an example of the embodiment, in order to increase the attachment area between the end, extending to the side surface of the substrate baseplate 1, of the first conductor layer 11 and the inner surface of the binding layer 13, the first conductor layer may be arranged in a multilayer structure, thereby increasing the end surface area of the end, extending to the side surface, of the first conductor layer 11, that is, the attachment area with the inner surface of the binding layer 13. The first guiding layer 11 in the embodiment may be, but not limited to, a multi-layer metal layer, and may also be a mixed-layer material composed of a metal layer or another conductive material (such as a conductive glue layer). For example, as shown in FIG. 2-E, the first conductor layer 11 includes a metal layer constituted by superposing at least two metal sublayers. The materials of the metal sublayers may be the same and may also be different, or some are the same and some are different. In an application example, the material of the metal sublayer is selected from, but not limited to, at least one of AL, Mo, Au, Ni, Ag and Cu.

Of course, in some application examples, the second conductor layer 12 may be a single-layer conductive structure and may also be a multi-layer conductive structure, which will not be described in detail here.

The connection mode of the binding layer 13 and the second conductor layer 12 in the embodiment may be flexibly set. For the convenience of understanding, description is made below with reference to a plurality of examples.

Example 1: as shown in FIG. 2-D, one end of the second conductor layer 12 also extends to the side surface (the side surface is the side surface where the corresponding first conductor layer extends) and is flush with the side surface. The second conductor layer 12 extends to one end of the side surface and is attached to the inner surface of the binding layer 13. The lower end 132 (the lower end 132 is the end, away from the top surface of the substrate baseplate 1, of the binding layer) of the binding layer 13 may be flush with the second conductor layer 12 (that is, the end face of the lower end 132 and the lower surface (the lower surface is the surface away from the bottom surface of the substrate baseplate 1) of the second conductor layer 12), and may also not be flush with the second conductor layer 12, which may be specifically flexibly set according to requirements.

Example 2: as shown in FIG. 2-B, the lower end 132 of the binding layer 13 extends to the bottom surface and is superimposed on the corresponding second conductor layer 12. Electrical connection is implemented by this vertical superposition (that is, overlap) mode, which can improve the contact area therebetween and the reliability of the connection. In the example, the second conductor layer 12 may not extend to the side surface of the substrate baseplate 1, and in the example shown in FIG. 2-B, the second conductor layer 12 extends to the side surface of the substrate baseplate 1. Of course, in other application examples, the second conductor layer 12 may not extend to the side surface of the substrate baseplate 1, as shown in FIG. 2-A, for example. At this moment, the end, extending to the side surface, of the second conductor layer 12 may also be attached to the inner surface of the binding layer 13 at the same time, thus further increasing the contact area therebetween. That is, in the embodiment, while the lower end of the binding layer may be vertically superposed with the second conductor layer, the end, extending to the side surface of the substrate baseplate, of the second conductor layer may also be in attachment contact with the inner surface of the binding layer.

Example 3: referring to FIG. 2-C, the difference between this example and the connection structure shown in FIG. 2-B in Example 2 is that the lower end 132 of the binding layer 13 extends to the bottom surface, and is in attachment contact with the end face of one end of the corresponding second conductor layer 12.

Of course, the connection structure between the binding layer and the second conductor layer is not limited to a plurality of structures shown in the above examples, but may also be flexibly replaced with another structure, which will not be described in detail here.

In an example of this example, in order to avoid the problem of wire breakage when the binding layer extends to the bottom surface of the substrate baseplate, an area where at least one side surface (such as the side surface to which the first conductor layer extends) of the substrate baseplate and the bottom surface intersect may be set as a chamfered area or a rounded area, and the lower end of the binding layer extends to the bottom surface along the chamfered area or rounded area, so as to avoid wire breakage as much as possible and further improve the reliability of electrical connection. In the embodiment, the specific size of the above chamfered area or rounded area may be flexibly set.

For example, as shown in FIG. 3-A and FIG. 3-B, the area where the side surface of the substrate baseplate 1 intersects with the bottom surface is set as a chamfered area 100, and the lower end 132 of the binding layer 13 extends to the bottom surface of the substrate baseplate 1 along the chamfered area 100. Of course, the chamfered area 100 in the example may also be replaced with a rounded area 101 shown in FIG. 3-C, or another transitional area capable of avoiding wire breakage, which will not be described in detail here.

In an example of the embodiment, in order to further improve the attachment strength between the binding layer and the side surface of the substrate baseplate, at least a part of the area where the binding layer is attached, on the side surface of the substrate baseplate may be set as a rough surface, so as to improve the attachment strength therebetween. For example, the whole area of the attached layer may be set as a rough surface, or only a part thereof may be set as a rough surface, or the whole area of the side surface of the substrate baseplate may be directly set as a rough surface, and the rough surface may be formed by providing a groove and/or a bump on the side surface and may also be formed by grinding the side surface, which will not be described in detail here. In the embodiment, the roughness of the rough surface may be flexibly set. For example, the roughness Sa may be set to, but not limited to, greater than or equal to 0.1 μm and smaller than or equal to 0.5 μm.

In an example of the embodiment, a groove penetrating through the top surface and bottom surface of the substrate baseplate may be arranged at the position, corresponding to an arrangement area of the binding layer, on the side surface, where the binding layer needs to be arranged, of the substrate baseplate, and the binding layer may be directly arranged in the groove, so that the attachment area between the binding layer and the substrate baseplate and the attachment strength therebetween can be improved. Also, the binding layer can be arranged in the groove, so that the size of the binding layer protruding from the side surface of the substrate baseplate can be reduced as much as possible, and the side frame width of the display backplane may be further reduced. It is to be understood that the shape and size of the groove in the example may be flexibly set according to application requirements. For example, the cross-sectional shape of the groove may be, but not limited to, a regular shape such as a rectangle, an arc and a triangle, and may also be an irregular shape. For the convenience of understanding, description is made below with an arc groove as an example.

Referring to the substrate baseplate 1 shown in FIG. 4, a plurality of grooves A11 are formed on the side surface A1 thereof, and the grooves A11 are arc grooves. The end face of the end, extending to the side surface A1, of the first conductor layer 11 on the top surface of the substrate baseplate 1 is flush with the inner surface of the groove A11, so that the binding layer may be arranged in the groove A11. In an example of the embodiment, the outer surface (the surface, away from the substrate baseplate, of the binding layer) of the binding layer may be set on the same plane as the area, where the groove A11 is not arranged, on the side surface A1, that is, set flush with the side surface A1, so as to reduce the side frame width of the manufactured display backplane as much as possible. Of course, in some application examples, the outer surface of the binding layer may be set to protrude from the side surface A1, or the outer surface of the binding layer may be set to be located in the groove A11.

In the embodiment, the combination mode between the upper end of the binding layer and the encapsulation layer formed on the top surface of the substrate baseplate may be that at least a part of the upper end of the binding layer is embedded in the encapsulation layer, and may also be that the inner surface of the binding layer is attached to the side surface of the encapsulation layer. Herein, in order to improve the display effect and further reduce the side frame of the display backplane visually to achieve the effect of basically no side frame visually, the distance between the upper end of the binding layer and the bottom surface may be set to be smaller than the distance between the upper surface of the encapsulation layer and the bottom surface. That is, the upper surface of the encapsulation layer is higher than the upper end of the binding layer, so that some light rays may be emitted through the side surface of the encapsulation layer, thus basically achieving the effect of no side frame visually. Herein, the upper surface of the encapsulation layer is the surface, away from the top surface, of the encapsulation layer.

In an example of the embodiment, the display backplane may further include a protective layer covering the binding layer, so as to protect the binding layer. The protective layer in the embodiment may be, but not limited to, an insulating layer and may also be, but not limited to, a conductor layer with certain conductivity. When the protective layer is an insulating layer, one binding layer may correspond to one protective layer, or a plurality of binding layers may be directly covered by one protective layer (at this moment, adjacent binding layers are also covered by the protective layer). In the embodiment, the protective layer may be a transparent layer and may also be set as a non-transparent layer according to requirements. The arrangement of the protective layer may prevent the binding layers between adjacent display backplanes from colliding and being damaged when a plurality of display backplanes are spliced to form a large-size display screen. In one example, in order to improve the visual effect at the splicing position, the protective layer may be set as a black protective layer, such as but not limited to a black ink layer or a first black glue layer. Herein, the thickness of the black ink layer or the first black glue layer may be flexibly set according to requirements, for example, set to be greater than or equal to 3 μm and less than or equal to 10 μm. An Optical Density (OD) value of the protective layer may also be flexibly set, for example, set to be, but not limited to, greater than or equal to 2.

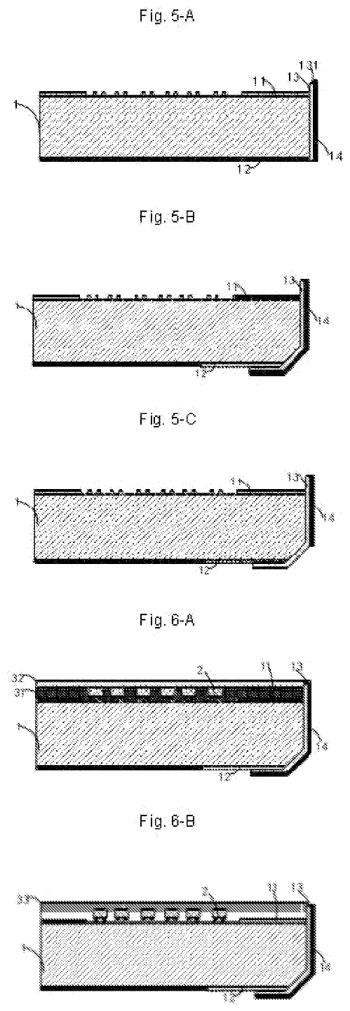

For example, as shown in FIG. 5-A, the display backplane further includes a protective layer 14 covering the binding layer 13. In the example, the upper end of the protective layer 14 is higher than the upper end 131 of the binding layer 13.

For another example, as shown in FIG. 5-B, the display backplane further includes a protective layer 14 covering the binding layer 13. In the example, the upper end of the protective layer 14 is flush with the upper end 131 of the binding layer 13.

It is to be understood that the protective layer in the embodiment may completely cover the outer surface of the binding layer 13 and may also only partially cover the outer surface of the binding layer 13, as shown in FIG. 5-C, for example. Flexible setting may be specifically implemented according to requirements.

According to the display backplane provided by the embodiment, a metal wire area for electrically connecting the driving circuit to the outside does not need to be reserved on a front surface of the substrate baseplate, but the area is arranged on a back surface of the substrate baseplate, so that the substrate baseplate has a narrow side frame, the width of the side frame may reach half the distance between corresponding light-emitting chips, or even smaller, the visual effect with no side frame may be achieved in visual effect, and the visual effect of seamless splicing may be basically achieved when being spliced into a large display screen. In addition, the binding layer is not only attached to the side surface of the substrate baseplate, but the upper end thereof is also higher than the top surface of the substrate baseplate, so that combination with the encapsulation layer may be achieved, the attachment firmness of the binding layer may be improved, the situation that the binding layer falls off or loosens from the side surface to cause poor conductivity is avoided, the manufacturing yield of the display backplane is improved, and the cost is reduced.

In an example of the embodiment, the display backplane further includes an encapsulation layer and a plurality of micro light-emitting chips. The plurality of micro light-emitting chips are fixedly arranged on the top surface of the substrate baseplate and electrically connected to the chip bonding area circuit, and the encapsulation layer is arranged on the top surface of the substrate baseplate and combined with the upper end of the binding layer to cover the micro light-emitting chips. Of course, in some application scenarios, at least one light-emitting surface of at least one micro light-emitting chip may also be exposed to the encapsulation layer.

The micro light-emitting chip in the embodiment may include, but is not limited to, at least one of a Mini LED chip and a Micro LED chip. The micro light-emitting chip may be transferred to the top surface of the substrate baseplate by various chip transfer methods, and bonded with a corresponding bonding area in the driving circuit.

In the embodiment, the encapsulation layer structure may be flexibly set, and description is made below with a plurality of structural examples.

Example 1: the encapsulation layer includes a second black glue layer covering the top surface and a transparent glue layer or a translucent layer arranged on the second black glue layer. At least one light-emitting surface of the micro light-emitting chip is exposed to the second black glue layer. For example, referring to the display backplane shown in FIG. 6-A, a micro light-emitting chip 2 is bonded on the top surface of the substrate baseplate 1. The micro light-emitting chip may include, but is not limited to, a blue light-emitting chip, or include, but is not limited to, a blue light-emitting chip, a red light-emitting chip and a green light-emitting chip. The top surface of the substrate baseplate 1 is provided with a second black glue layer 31, the light-emitting surface of the front surface of the micro light-emitting chip is exposed to the second black glue layer 31, and a translucent glue layer 31 is arranged on the second black glue layer 31. In an application example, the thickness of the second black glue layer 31 may be, but not limited to, 50 μm to 60 μm, and the thickness of the translucent glue layer 31 may be, but not limited to, 150 μm to 200 μm, in another application example. In some application examples, the translucent glue layer 31 or the transparent glue layer may be replaced with a substrate with light transmittance. In the example shown in FIG. 6-A, the upper end of the binding layer 13 is embedded into the encapsulation layer. Specifically, the upper end of the binding layer is embedded into the translucent glue layer 31 and is lower than the upper top surface of the translucent glue layer 31. In the example, the upper end of the protective layer is also embedded into the translucent glue layer 31, although same may not be embedded into the translucent glue layer 31.

Example 2: The encapsulation layer includes a gray glue layer covering the top surface and covering a plurality of micro light-emitting chips. The gray glue layer has light transmittance, and the light transmittance of the gray glue layer is lower than the light transmittance of the translucent glue layer. For example, referring to the display backplane shown in FIG. 6-B, the micro light-emitting chip 2 is bonded on the top surface of the substrate baseplate 1. A gray glue layer 33 is arranged on the top surface of the substrate baseplate 1. The thickness of the gray glue layer 33 may be flexibly set. In the example shown in FIG. 6-B, the inner surface of the upper end of the binding layer 13 is attached to the inner surface of the encapsulation layer, specifically to the inner surface of the gray glue layer 33. The upper end of the binding layer 13 may be arranged to be flush with the upper end of the protective layer 14 or lower than the upper end of the protective layer 14. The upper end of the protective layer 14 may be arranged to be flush with the upper surface of the gray glue layer 33 or lower than the gray glue layer 33.

Example 3: in the example, the encapsulation layer may also include a color film layer (also called a light-emitting conversion layer) for color conversion of the light emitted by the micro light-emitting chip. The color film layer may be directly disposed on a front light-emitting surface of the micro light-emitting chip 2, and may also disposed on the second black glue layer 31, or on the translucent glue layer 32, or on the gray glue layer 33 in the above example.

Example 4: in the embodiment, on the basis of the above examples, a strippable glue layer located at the bottommost layer may be further included, and the strippable glue layer does not cover the chip bonding area circuit.

Of course, it is to be understood that the structure of the encapsulation layer in the embodiment is not limited to the structure of the above example. For example, in some application examples, the encapsulation layer may also include an OC glue layer directly arranged between the top surface of the substrate baseplate 1 and the second black glue layer 31. Of course, other glue layers or conversion layers may be arranged according to requirements, which will not be described in detail here. In addition, in the embodiment, the specific materials and manufacturing processes of the above layers may be flexibly set, which will not be described in detail here.

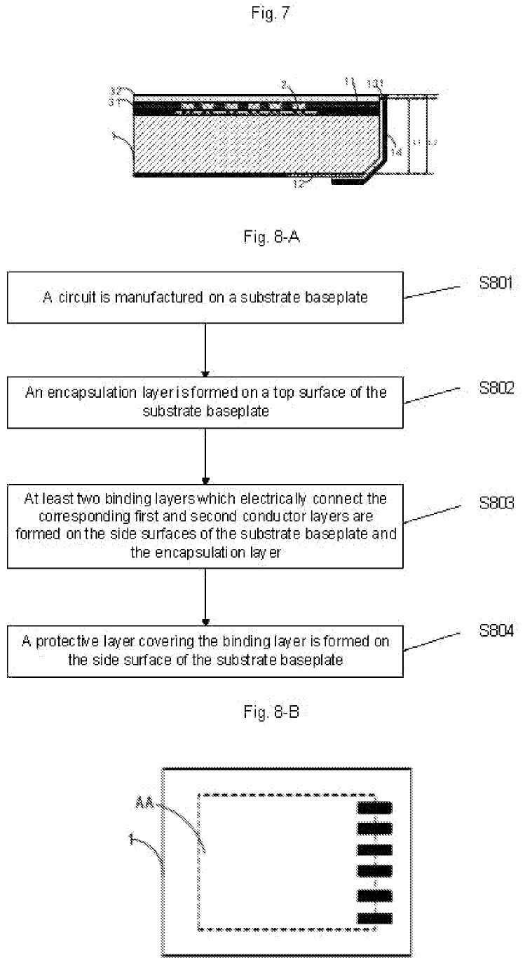

In an example of the embodiment, as shown in FIG. 7, the distance L1 between the upper end 131 of the binding layer and the bottom surface of the substrate baseplate 1 is smaller than the distance L2 between the upper surface (in the example, the upper surface of the translucent glue layer 32 in FIG. 7) of the encapsulation layer and the bottom surface of the substrate baseplate 1. That is, the upper surface of the encapsulation layer is higher than the upper end 131 of the binding layer, so that some light rays may be emitted through the side surface of the encapsulation layer, which basically achieves the side frame-free effect visually. Moreover, when spliced into a large display screen, the visual effect of seamless splicing may be basically achieved.

### Another Optional Embodiment

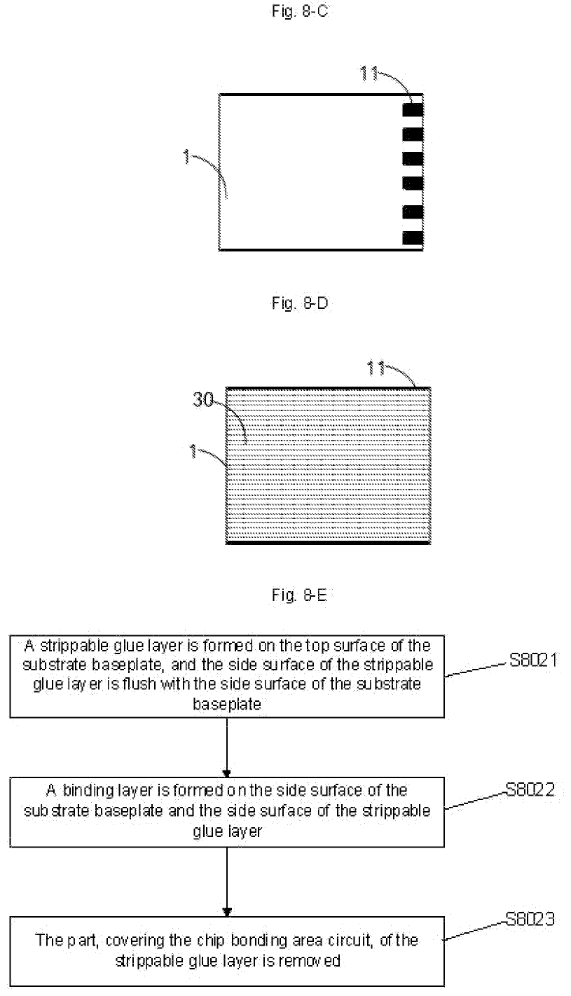

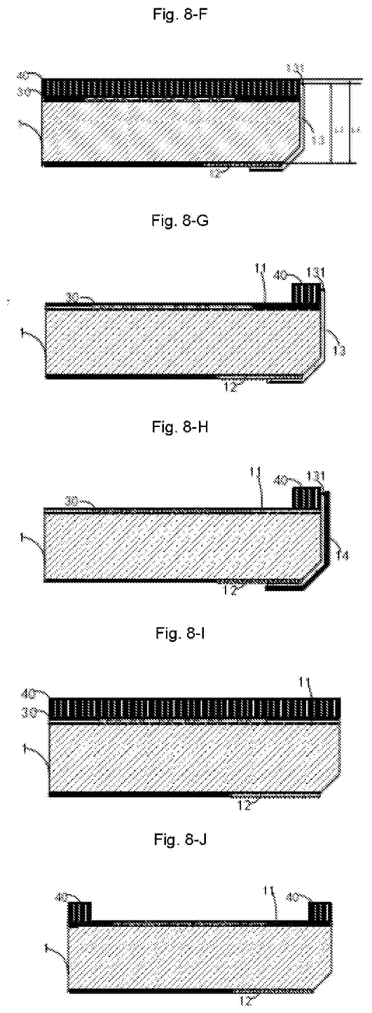

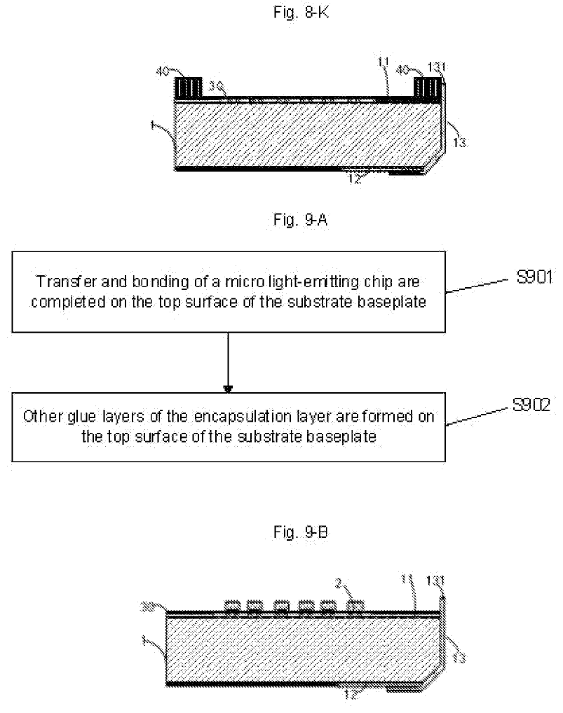

The embodiment provides a manufacturing method of a display backplane, which may be used to manufacture the display backplane shown in the above embodiment, as shown in FIG. 8-A, including but not limited to the following operations.

At S801, a circuit is manufactured on a substrate baseplate.

In the operation, it is included that a driving circuit is manufactured on the top surface of the substrate baseplate, and at least two mutually insulated second conductor layers are manufactured on the bottom surface of the substrate baseplate. The manufactured driving circuit includes at least two mutually insulated first conductor layers. One end of the first conductor layer extends to the side surface of the substrate baseplate and is flush with the side surface, and the second conductor layer manufactured on the bottom surface of the substrate baseplate corresponds to the first conductor layer.

It is to be understood that in the embodiment, there is no limitation to the way of manufacturing the circuit on the substrate baseplate. For the convenience of understanding, description is made below with the substrate baseplate as a glass substrate as an example, and the process of manufacturing a circuit on the substrate baseplate as an example.

In the example, the substrate baseplate may adopt active-mode driving (AM mode) or passive-mode driving (PM mode). In the manufacturing process, as shown in FIG. 8-B, when the metal on the substrate baseplate 1 is filmed to form a circuit, a metal layer at the edge of a display area AA on the substrate baseplate 1 is kept to extend beyond a display boundary. Then, the substrate baseplate 1 is cut along the edge of the display area AA On the top and bottom surfaces of the substrate baseplate 1, the metal layers extending out of the edge of the display area AA are cut to form corresponding first and second conductor layers, respectively. For example, as shown in FIG. 8-C, the first conductor layer 11 formed on the top surface of the substrate baseplate 1 after cutting.

In the embodiment, in order to avoid short circuit between adjacent conductor layers when a bonding layer is manufactured on the side surface of the substrate baseplate 1, a layer of insulating photoresist is enabled to cover a metal line after a circuit pattern is formed by film formation, exposure and development on the metal line (that is, a layer of insulating photoresist is formed on the front surface and back surface of the substrate baseplate 1). At this moment, the photoresist layer covers all the metal lines, and the photoresist layer on the surface of the conductor layer corresponding to the edge of the display area AA may be exposed and developed for windowing. For example, referring to a photoresist layer 30 shown in FIG. 8-D.

In some application examples, since the thickness of a single metal layer is small, in order to increase the attachment (which may also call overlap joint) area between the end, extending to the side surface of the substrate baseplate 1, of the first conductor layer and the inner surface of the binding layer, a plurality of metal sublayers may be sequentially superposed through but not limited to a yellow light process to form the first conductor layer with a multilayer structure, so as to increase the thickness of the first conductor layer by times and ensure the attachment area between the first conductor layer and the binding layer. The multilayer structure of the formed first conductor layer may refer to, but is not limited to, what is shown in FIG. 2-E, which will not be described in detail here.

At S802, an encapsulation layer is formed on the top surface of the substrate baseplate.

At S803, at least two binding layers which electrically connect the corresponding first and second conductor layers are formed on the side surfaces of the substrate baseplate and the encapsulation layer.

In the example, the formed at least two binding layers are insulated from each other, the end, extending to the side surface, of the first conductor layer is attached to the inner surface of the binding layer, and the upper end of the binding layer is higher than the top surface of the substrate baseplate, and is combined with the encapsulation layer arranged on the top surface.

It is to be understood that in the embodiment, the mode of forming the binding layer on the side surfaces of the substrate baseplate and the encapsulation layer may be flexibly set. In some examples, before at least two binding layers which electrically connect the corresponding first and second conductor layers are formed on the side surfaces of the substrate baseplate and the encapsulation layer, at least one of the following may be included but is not limited to.

Chamfering processing is performed on an area where the side surface and the bottom surface of the substrate baseplate intersect to form a chamfered area or rounding processing is performed to form a rounded area, thereby avoiding the situation that the lower end of the binding layer is broken in the extension process when the binding layer is formed.

An area, where the binding layer needs to be formed, on the side surface of the substrate baseplate is at least ground to form a rough surface.

A groove is formed in the area, where the binding layer needs to be formed, on the side surface of the substrate baseplate. In some examples, an inner wall of the groove may also be processed as a rough surface. Of course, the groove in the embodiment may also be pre-formed. For example, in the process of manufacturing the substrate baseplate, a through hole may be opened at a junction area of the substrate baseplate, then cutting is performed along the center of the through hole, and a corresponding position on the side surface of a single substrate baseplate obtained after cutting is preset with the groove.

For the convenience of understanding, description is made below with a plurality of binding layer forming examples. As shown in FIG. 8-E, the following operations are included but not limited to.

At S8021, a strippable glue layer is formed on the top surface of the substrate baseplate, and the side surface of the strippable glue layer is flush with the side surface of the substrate baseplate.

At S8022, a binding layer is formed on the side surface of the substrate baseplate and the side surface of the strippable glue layer. The distance between the upper end of the binding layer and the bottom surface is less than or equal to the distance between the upper surface of the strippable glue layer and the bottom surface. The upper surface of the strippable glue layer is the surface, away from the top surface, of the strippable glue layer.

For example, as shown in FIG. 8-F, a strippable glue layer 40 is arranged on the top surface of the substrate baseplate 1, and then a binding layer 13 is formed on the side surface of the substrate baseplate 1 and the side surface of the strippable glue layer 40. The distance L3 between the upper end 131 of the binding layer 13 and the bottom surface of the substrate baseplate 1 is less than or equal to the distance L4 between the upper surface of the strippable glue layer 40 and the bottom surface of the substrate baseplate 1, and the upper surface of the strippable glue layer is the surface, away from the top surface of the substrate baseplate 1, of the strippable glue layer.

In one example, the binding layer may be formed on the side surface of the substrate baseplate and the side surface of the strippable glue layer by, but not limited to, methods such as printing of metal paste (such as silver paste), sputtering of a metal film, transfer printing of ink. After being formed, the bonding layer may be subjected to curing processing. According to the difference of materials, Oven curing (for example, low-temperature curing of the silver paste may be 80° C. for about 40 minutes, and high-temperature curing of the silver paste may be 180° C. for 30 minutes) or laser curing (for example, instantaneous 260° C. laser is performed at a rate of 5 mm/sec) may be adopted but not limited to.

At S8023, the part, covering the chip bonding area circuit, of the strippable glue layer is removed.

After the removal, at least an edge area of the strippable glue layer remains. For example, as shown in FIG. 8-G, after the strippable glue layer 40 is removed, the remaining edge area (the edge area at least includes the edge area of the side where the binding layer is arranged) is combined with the upper end of the binding layer 13, and the width of the remaining edge area may be flexibly set, for example, set to be 50 μm to 70 μm. In an example of the embodiment, the strippable glue layer may adopt, but is not limited to, a photoresist layer, and the photoresist that needs to be removed may be removed by, but not limited to, a way of windowing the photoresist. Of course, in the operation, the photoresist layer 30 may also be removed.

After the operation, bonding of the micro light-emitting chip may be completed on the exposed chip bonding area circuit, and other glue layers of the encapsulation layer may be continuously formed, such as:

a second black glue layer is formed on the top surface, and a transparent glue layer or a translucent glue layer is formed on the second black glue layer; or, a gray glue layer covering a plurality of micro light-emitting chips is formed on the top surface.

For the convenience of understanding, description is made below with reference to FIG. 9-A, which includes but is not limited to the following operations.

At S901, transfer and bonding of the micro light-emitting chip are completed on the top surface of the substrate baseplate.

For example, for the Mini LED chip, Surface Mounted Technology (SMT) process may be adopted but not limited to. For the Micro LED chip, bonding may be performed by adopting Anisotropic Conductive Film (ACF) material bonding or Under Bump Metallization (UBM) layer eutectic mode. For example, as shown in FIG. 9-B, bonding of the micro light-emitting chip 2 is completed on the top surface of the substrate baseplate 1.

At S902, other glue layers of the encapsulation layer are formed on the top surface of the substrate baseplate.

For example, after the bonding of the micro light-emitting chip is completed in S901, a layer of 50 μm to 60 μm black glue material (that is, the second black glue layer, the black glue layer may be a composite material of reactive polyimide and epoxy resin, in which polyimide is used as a curing agent, while carbon and other additives are added to increase blackness) may be encapsulated in vertical and horizontal gaps of the micro light-emitting chip, on the top surface of the substrate baseplate 1 by using but not limited to a vacuum hot pressing process. In the example, the encapsulated black glue layer may cover the strippable glue layer, and the upper surface of the black glue layer does not exceed the upper surface of the micro light-emitting chip (that is, the front light-emitting surface). That is, after glue encapsulation, the black glue beyond the upper surface of the micro light-emitting chip may be removed by adopting but not limited to a plasma mode. The black glue layer may enhance the brightness of a brightness display area and improve light reflection of the front surface. Then, a translucent glue layer is encapsulated on the upper surface of the black glue layer by vacuum hot pressing. The thickness of the translucent glue layer is 150 μm-200 μm. The material may also adopt but not limited to an epoxy resin composite material with polyimide as the curing agent.

However, in some examples, the above-mentioned black glue layer and translucent glue layer may be replaced with a gray glue layer with lower light transmittance than the translucent glue layer.

At S804, a protective layer covering the binding layer is formed on the side surfaces of the substrate baseplate and the encapsulation layer, as shown in FIG. 8-H. It is to be understood that this operation is an optional operation.

For example, a layer of black protective glue (that is, the first black glue layer) or a black ink layer is enabled to cover the outer surface of the binding layer, which may play a role in preventing the line from being damaged by collision and improving the visual effect of the splicing joint. For example, in an application scenario, a layer of black protective glue may be covered. The black protective glue may adopt but is not limited to a modified acrylic resin material with a black pigment filler, etc., and has high adhesion. The thickness thereof may be set to be 3 μm to 8 μm in a single part, and the OD value thereof is greater than 2. The material of the gray glue may include, for example, silicone resin mixed with carbon powder, which is not limited here.

In another example of the embodiment, after the strippable glue layer is formed on the top surface of the substrate baseplate, the part, covering the chip bonding area circuit, of the strippable glue layer may be removed first, and then the binding layer is formed on the side surface of the substrate baseplate and the side surface of the strippable glue layer.

For example, as shown in FIG. 8-I, a strippable glue layer 40 is first formed on the top surface of the substrate baseplate 1. As shown in FIG. 8-J, the part, covering the chip bonding area circuit, of the strippable glue layer 40 is removed, and the strippable glue layer 40 with a set width is kept at the edge of the substrate baseplate 1. As shown in FIG. 8-K, a binding layer 13 is formed on the side surface of the substrate baseplate 1 and the side surface of the strippable glue layer.

The display backplane manufactured by the manufacturing method of the display backplane no longer needs to reserve a metal circuit connection area on the top surface of the substrate baseplate, but implements the connection to the outside through the second conductor layer on the bottom surface of the substrate baseplate, so the manufactured display backplane has a narrow side frame. The manufactured binding layer is not only attached to the side surface of the substrate baseplate, but the upper end thereof is also higher than the top surface of the substrate baseplate, so that combination with the encapsulation layer may be achieved, and the attachment firmness performance is better guaranteed.

### Yet Another Optional Embodiment

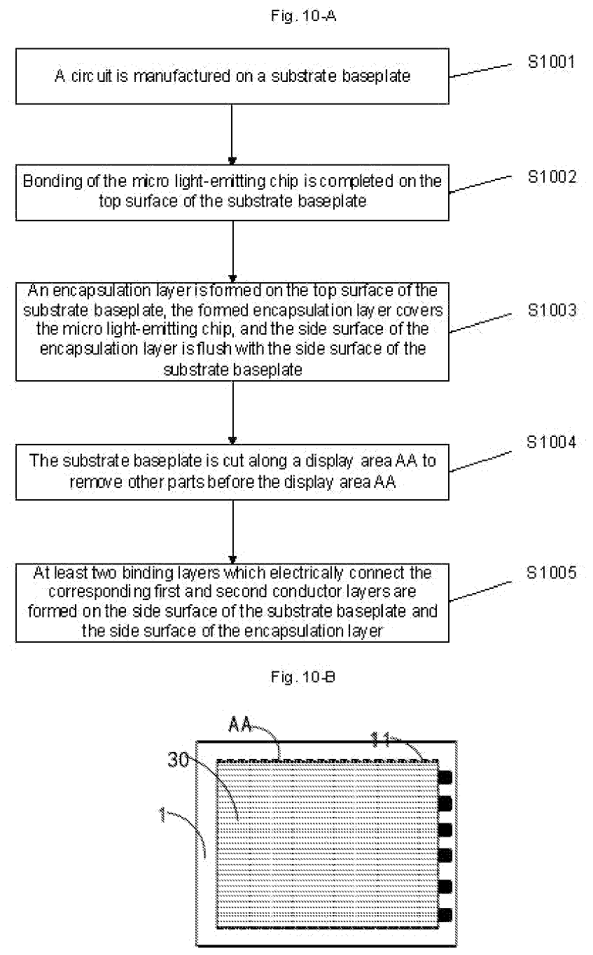

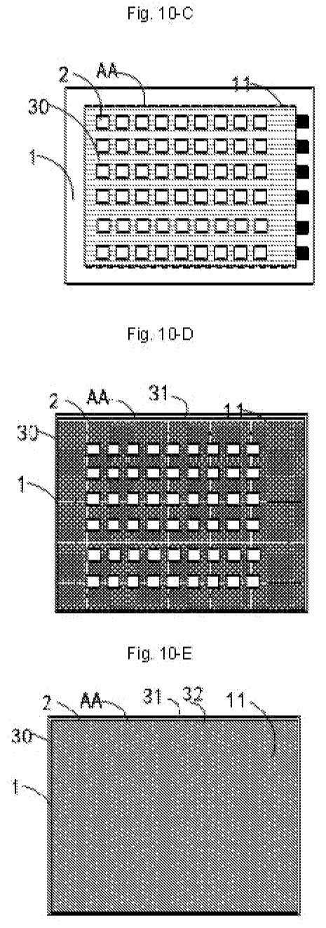

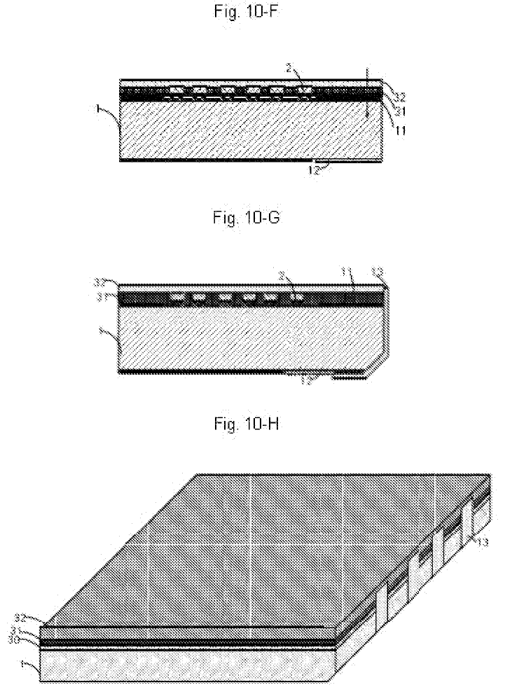

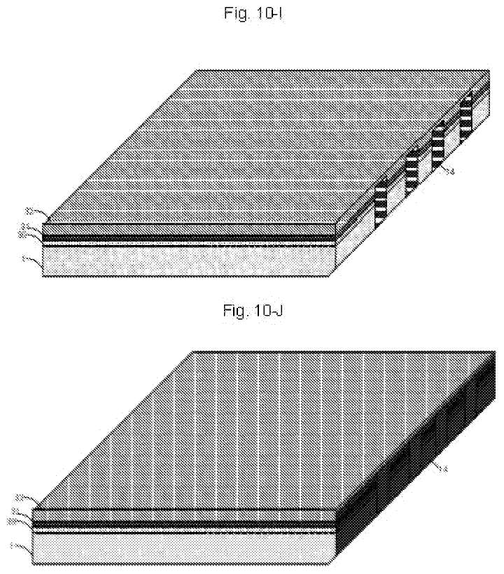

The embodiment also provides a manufacturing method of a display backplane, which mainly includes a plurality of processes of baseplate manufacturing, chip bonding, encapsulation layer formation and binding layer manufacturing. For example, as shown in FIG. 10-A, the manufacturing method of the display backplane includes but is not limited to the following operations.

At S1001, a circuit is manufactured on a substrate baseplate.

In the operation, the process of manufacturing the circuit on the substrate baseplate may refer to the process in S801 in the above embodiment, but after a circuit pattern is formed in a display area AA on the substrate baseplate 1, same is not cut first. Moreover, in order to avoid short circuit between adjacent conductor layers when a bonding layer is manufactured on the side surface of the substrate baseplate 1, a layer of insulating photoresist is enabled to cover a metal line after a circuit pattern is formed by film formation, exposure and development on the metal line. At this moment, the photoresist layer covers all the metal lines, and the photoresist layer on the surface of the conductor layer corresponding to the edge of the display area AA may be exposed and developed for windowing, and the obtained structural diagram is shown in FIG. 10-B.

At S1002, bonding of the micro light-emitting chip is completed on the top surface of the substrate baseplate.

In the embodiment, the transfer and bonding process of the micro light-emitting chip will not be described in detail here. An example after bonding is shown in FIG. 10-C. The micro light-emitting chip in the figure may be a blue light-emitting chip, and may also include a blue light-emitting chip, a red light-emitting chip and a green light-emitting chip.

At S1003, an encapsulation layer is formed on the top surface of the substrate baseplate, the formed encapsulation layer covers the micro light-emitting chip, and the side surface of the encapsulation layer is flush with the side surface of the substrate baseplate.

In the embodiment, the process of forming the encapsulation layer on the top surface of the substrate baseplate may refer to, but is not limited to, the process of forming the encapsulation layer in the above example. Description is made below with the encapsulation layer including the second black glue layer and the translucent glue layer as an example.

A second black glue layer 31 may be first formed on the top surface of the substrate baseplate, as shown in FIG. 10-D, and then a translucent layer 32 is formed on the second black glue layer 31, as shown in FIG. 10-E. Herein, the hardness of the photoresist layer 30, the second black glue layer 31 and the translucent layer 32 after curing may be set to be greater than or equal to 2H to meet the subsequent cutting requirements.

At S1004, the substrate baseplate is cut along the display area AA to remove other parts before the display area AA. It is to be understood that the operation in the embodiment is an optional operation, and the operation may not be executed when the entire top surface of the substrate baseplate is a display area.

In the embodiment, after the encapsulation layer is formed, four sides of the substrate baseplate may be cut according to the size of the display area AA, and the cutting mode may be but not limited to laser cutting, cutter cutting and other processes. For example, referring to a cutting direction shown by an arrow in FIG. 10-F, a laser mode may be adopted to cut down from the encapsulation layer, the encapsulation layer is cut by laser, and further cut to the depth of 70 μm-80 μm of the substrate baseplate, and then the area outside the display area AA is removed by manual splitting or mechanical automatic splitting. Of course, in some examples, same may also be cut to the bottom surface of the substrate baseplate.

At S1005, at least two binding layers which electrically connect the corresponding first and second conductor layers are formed on the side surface of the substrate baseplate and the side surface of the encapsulation layer.

The at least two binding layers formed in the operation are insulated from each other, and the end, extending to the side surface, of the first conductor layer is attached to the inner surface of the binding layer, and the upper end of the binding layer is higher than the top surface and combined with the encapsulation layer, as shown in FIGS. 10-G and 10-H.

It is to be understood that in the embodiment, after S1004 is executed and before S1005 is executed, at least one of the following operations may be selectively executed, but not limited to.

An area, where the binding layer needs to be formed, on the side surface of the substrate baseplate is at least ground to form a rough surface. For example, the side surface (optionally, the side surface of the encapsulation layer may be simultaneously ground as required) of the cut substrate baseplate may be ground by adopting but not limited to an emery grinding bar. The mesh number of the grinding bar may be 800, 1000, 1500, etc., and the surface roughness Sa after grinding is greater than or equal to 0.1 μm and less than or equal to 0.3 μm. The roughness may improve the adhesion of the conductive material used to manufacture the binding layer, thereby improving the combination strength among the binding layer, the substrate baseplate and the encapsulation layer.

Chamfering processing is performed on an area where the side surface and the bottom surface of the substrate baseplate intersect to form a chamfered area or rounding processing is performed to form a rounded area, thereby avoiding the situation that the lower end of the binding layer is broken in the extension process when the binding layer is formed. In one example, the bottom of the substrate baseplate may be chamfered or rounded in the process of grinding the side surface of the substrate baseplate, and the size of the chamfered angle or rounded angle may be less than or equal to 100 μm.

A groove is formed in the area, where the binding layer needs to be formed, on the side surface of the substrate baseplate. In some examples, an inner wall of the groove may also be processed as a rough surface. Of course, the groove in the embodiment may also be pre-formed. For example, in the process of manufacturing the substrate baseplate, a through hole may be opened at a junction area of the substrate baseplate, then cutting is performed along the center of the through hole, and a corresponding position on the side surface of a single substrate baseplate obtained after cutting is preset with the groove. Of course, in some examples, the groove may also penetrate the encapsulation layer.

At S1006, on the side surface of the substrate baseplate and the side surface of the encapsulation layer, a protective layer covering the binding layer is formed. It is to be understood that this operation is an optional operation.

For example, a layer of black protective glue (that is, the first black glue layer) or a black ink layer is enabled to cover the outer surface of the binding layer, which may play a role in preventing the line from being damaged by collision and improving the visual effect of the splicing joint. For example, in an application scenario, a layer of black protective glue may be covered. The black protective glue may adopt but is not limited to a modified acrylic resin material with a black pigment filler, etc., and has high adhesion. The thickness thereof may be set to be 5 μm to 7 μm in a single part, and the OD value thereof is greater than or equal to 2.

For example, as shown in FIG. 10-I, the display backplane includes a plurality of protective layers 14 in one-to-one correspondence with a plurality of binding layers 13, and each protective layer 14 covers the corresponding binding layer 13. In the example, the protective layer 14 may be an insulating protective side and may also be arranged as a conductive protective layer as required.

For another example, as shown in FIG. 10-J, the display backplane includes a protective layer 14 arranged on the side surface of the substrate baseplate, and the protective layer 14 directly covers a plurality of binding layers 13. In the example, the protective layer 14 is an insulating protective layer.

### Another Optional Embodiment

The embodiment further provides a display panel, which includes the display backplane as shown above. A display screen is also provided, which includes a display panel and a frame, and the display panel is fixed on the frame. The display screen has a narrow side frame, and the substrate may achieve a side frame-free effect in visual effect, so the display effect and viewing experience are better, and same may be applied to but not limited to various intelligent mobile terminals, vehicle-mounted terminals, PCs, monitors, electronic advertisement boards, etc.

The embodiment also provides a spliced display screen, including the spliced display screen which may be formed by splicing at least two display screens as shown above. Since the side frames of the display screens are narrow, the width of a splicing gap between adjacent display screens after being spliced may be basically consistent with the distance between adjacent light-emitting chips in the display area of each display screen, and a seamless effect may be achieved in visual effect.

It is to be understood that the application of the present application is not limited to the above examples, and those skilled in the art may make improvements or changes according to the above description. A1 these improvements and changes shall fall within the scope of protection of the appended claims of the application.

1. A display backplane, comprising:
a substrate baseplate, the substrate baseplate being provided with a top surface and a bottom surface which are opposite to each other, the top surface being provided with a driving circuit for driving a micro light-emitting chip, the driving circuit comprising a chip bonding area circuit and at least two mutually insulated first conductor layers connected to the chip bonding area circuit, one end of each first conductor layer extending to a side surface of the substrate baseplate and being flush with the side surface, and the bottom surface being provided with at least two mutually insulated second conductor layers corresponding to the at least two first conductor layers;
an encapsulation layer arranged on the top surface; and
at least two binding layers attached to the side surface and electrically connecting the corresponding first conductor layer and second conductor layer respectively;
wherein the at least two binding layers are mutually insulated, the end, extending to the side surface, of the first conductor layer being attached to an inner surface of the binding layer, an upper end of the binding layer being higher than the top surface and combined with the encapsulation layer arranged on the top surface, the inner surface of the binding layer being the surface, close to the substrate baseplate, of the binding layer, and the upper end of the binding layer being the end, close to the top surface, of the binding layer.

2. The display backplane according to claim 1, wherein a lower end of the binding layer extends to the bottom surface and is superimposed on the corresponding second conductor layer, the lower end of the binding layer being the end, away from the top surface, of the binding layer;
and/or,
one end of the second conductor layer extends to the side surface and being flush with the side surface, and the second conductor layer extends to one end of the side surface and being attached to the inner surface of the binding layer.

3. The display backplane according to claim 2, wherein an area where the side surface of the substrate baseplate and the bottom surface of the substrate baseplate intersect is a chamfered area or a rounded area, and the lower end of the binding layer extends to the bottom surface along the chamfered area or the rounded area.

4. The display backplane according to claim 1, wherein a groove is formed in an area where the binding layer is attached to the side surface, and the binding layer is located in the groove;
and/or,
at least a part of the area where the binding layer is attached to the side surface is a rough surface.

5. The display backplane according to claim 4, wherein the binding layer is located in the groove, areas where the groove is not formed in an outer surface of the binding layer and the side surface of the binding layer are located on the same plane, and the outer surface of the binding layer is the surface, away from the substrate baseplate.

6. The display backplane according to claim 4, wherein the binding layer is located in the groove, and the upper end of the binding layer is at least partially embedded into the encapsulation layer.

7. The display backplane according to claim 1, wherein the inner surface of the binding layer is attached to a side surface of the encapsulation layer.

8. The display backplane according to claim 1, wherein a distance between the upper end of the binding layer and the bottom surface is smaller than a distance between the upper surface of the encapsulation layer and the bottom surface, the upper surface of the encapsulation layer being the surface, away from the top surface, of the encapsulation layer.

9. The display backplane according to claim 1, wherein the first conductor layer comprises a metal layer formed by superposing at least two metal sublayers.

10. The display backplane according to claim 1, further comprising a protective layer covering the binding layer.

11. The display backplane according to claim 10, wherein the protective layer is a black ink layer or a first black glue layer.

12. The display backplane according to claim 1, further comprising a plurality of micro light-emitting chips, wherein the plurality of micro light-emitting chips are fixedly arranged on the top surface and connected to the chip bonding area circuit.

13. A manufacturing method of a display backplane, comprising:
manufacturing a driving circuit on a top surface of a substrate baseplate, wherein the driving circuit comprises a chip bonding area circuit and at least two mutually insulated first conductor layers connected to the chip bonding area circuit, one end of each first conductor layer extending to a side surface of the substrate baseplate and being flush with the side surface of the substrate baseplate, a bottom surface of the substrate baseplate being provided with at least two mutually insulated second conductor layers corresponding to the at least two first conductor layers, and the top surface and the bottom surface being two opposite surfaces of the substrate baseplate;
forming an encapsulation layer on the top surface, wherein a side surface of the encapsulation layer is flush with the side surface of the substrate baseplate; and
forming at least two binding layers, which electrically connect the corresponding first conductor layer and second conductor layer, on the side surfaces of the substrate baseplate and the side surfaces of the encapsulation layer, wherein the at least two binding layers formed are mutually insulated, the end, extending to the side surface, of the first conductor layer being attached to an inner surface of the binding layer, an upper end of the binding layer being higher than the top surface and combined with the encapsulation layer, the inner surface of the binding layer being the surface, close to the substrate baseplate, of the binding layer, and the upper end of the binding layer being the end, close to the top surface, of the binding layer.

14. The manufacturing method of the display backplane according to claim 13, before forming the encapsulation layer on the top surface, further comprising:
completing bonding of the micro light-emitting chip on the chip bonding area circuit.

15. The manufacturing method of the display backplane according to claim 14, wherein forming the encapsulation layer on the top surface comprises:
forming a second black glue layer on the top surface, and forming a transparent glue layer or a translucent glue layer on the second black glue layer, wherein at least one light-emitting surface of the micro light-emitting chip is exposed to the second black glue layer;
or,
forming a gray glue layer covering the plurality of micro light-emitting chips on the top surface.

16. The manufacturing method of the display backplane according to claim 13, wherein forming the encapsulation layer on the top surface comprises:
forming a strippable glue layer on the top surface, wherein a side surface of the strippable glue layer is flush with the side surface of the substrate baseplate,
wherein forming at least two binding layers, which electrically connect the corresponding first conductor layer and second conductor layer, on the side surfaces of the substrate baseplate and the side surfaces of the encapsulation layer comprises:
after forming the binding layers on the side surface of the substrate baseplate and the side surface of the strippable glue layer, removing the part, covering the chip bonding area circuit, of the strippable glue layer;
or,
after removing the part, covering the chip bonding area circuit, of the strippable glue layer, forming a binding layer on the side surface of the substrate baseplate and the side surface of the strippable glue layer,
wherein a distance between the upper end of the binding layer and the bottom surface is smaller than a distance between the upper surface of the strippable glue layer and the bottom surface, the upper surface of the strippable glue layer being the surface, away from the top surface, of the strippable glue layer.

17. The manufacturing method of the display backplane according to claim 16, after forming the binding layer on the side surface of the substrate baseplate and the side surface of the strippable glue layer, further comprising:
completing bonding of the micro light-emitting chip on the chip bonding area circuit;
forming a second black glue layer on the top surface, and forming a transparent glue layer or a translucent glue layer on the second black glue layer, wherein at least one light-emitting surface of the micro light-emitting chip is exposed to the second black glue layer; or, forming a gray glue layer covering the plurality of micro light-emitting chips on the top surface.

18. The manufacturing method of the display backplane according to claim 13, before forming at least two binding layers, which electrically connect the corresponding first conductor layer and second conductor layer, on the side surfaces of the substrate baseplate and the encapsulation layer, further comprising:
performing chamfering processing on an area where the side surface and the bottom surface of the substrate baseplate intersect to form a chamfered area or performing rounding processing on the area where the side surface and the bottom surface of the substrate baseplate intersect to form a rounded area;
wherein forming at least two binding layers, which electrically connect the corresponding first conductor layer and second conductor layer, on the side surfaces of the substrate baseplate and the encapsulation layer comprises:
enabling the lower end of the binding layer to extend to the bottom surface along the chamfered area or the rounded area, wherein the lower end of the binding layer is the end, away from the top surface, of the binding layer;
and/or,
before forming at least two binding layers, which electrically connect the corresponding first conductor layer and second conductor layer, on the side surfaces of the substrate baseplate and the encapsulation layer, further comprising:
at least grinding an area, where the binding layer needs to be formed, on the side surface of the substrate baseplate to form a rough surface.

19. The manufacturing method of the display backplane according to claim 13, after forming at least two binding layers, which electrically connect the corresponding first conductor layer and second conductor layer, on the side surfaces of the substrate baseplate and the encapsulation layer, further comprising:
forming, on the side surface of the substrate baseplate and the side surface of the encapsulation layer, a protective layer covering the binding layer.

20. A display panel, comprising the display backplane of claim 1.
